(19) United States
(12) Patent Application Publication
(10) Pub. No.: US 2024/0297112 A1
(43) Pub. Date: Sep. 5, 2024

(54) PASSIVE COMPONENT MODULE

(71) Applicant: Texas Instruments Incorporated, Dallas, TX (US)

(72) Inventors: Sylvester Ankamah-Kusi, Dallas, TX (US); Rajen Murugan, Dallas, TX (US); Harshpreet Bakshi, Dallas, TX (US); Vivek Sridharan, Dallas, TX (US); Ruben Rolda, Plano, TX (US)

(21) Appl. No.: 18/498,188

(22) Filed: Oct. 31, 2023

Related U.S. Application Data
(60) Provisional application No. 63/487,874, filed on Mar. 1, 2023.

(51) Int. Cl. H01L 23/50; H01C 1/14; H01C 7/00; H01G 4/012; H01G 4/33; H01L 23/552; H01L 25/18; H01L 27/01

(52) U.S. Cl. CPC H01L 23/50; H01C 1/14; H01C 7/003; H01G 4/012; H01G 4/33; H01L 23/552; H01L 25/18; H01L 27/01

(57) ABSTRACT

A passive component module includes opposite first and second sides, a base extending to the second side, and a redistribution layer structure extending between the base and the first side, the redistribution layer structure including: a passive electronic component with a first component terminal and a second component terminal; a conductive metal trace that forms at least a portion of the passive electronic component; a dielectric layer abutting a portion of the conductive metal trace; a first terminal exposed along the first side and electrically coupled to the first component terminal; and a second terminal spaced apart from the first terminal and exposed along the first side, the second terminal electrically coupled to the second component terminal.

### CROSS-REFERENCE TO RELATED APPLICATION

This application claims priority to and benefit of U.S. Provisional Patent Application No. 63/487,874, filed on Mar. 1, 2023, and titled “Passive Component Module Design in Chip-First-Fan-Out-Technology”, the contents of which are hereby fully incorporated by reference.

### BACKGROUND

Integrated circuits and other electronic devices are often used in circuits with other components, including passive components. Integration of one or more passive components in a packaged electronic device can provide a cost effective compact solution compared with using external passive components on a host printed circuit board (PCB), and packaged electronic devices increasingly include integrated passive components. However, integrating passive components on-chip increases the area of the die, and adding surface mount technology (SMT passive components in a device package can significantly increase the packaged electronic device size and/or cost.

### SUMMARY

In one aspect, a passive component module is provided, having opposite first and second sides, a base extending to the second side, and a redistribution layer structure extending between the base and the first side. The redistribution layer structure includes a passive electronic component with a first component terminal and a second component terminal, a conductive metal trace that forms at least a portion of the passive electronic component, a dielectric layer abutting a portion of the conductive metal trace, a first terminal exposed along the first side and electrically coupled to the first component terminal, and a second terminal spaced apart from the first terminal and exposed along the first side, the second terminal electrically coupled to the second component terminal.

In another aspect, an electronic device includes a multilevel package substrate having a first substrate side with exposed conductive leads and an opposite second substrate side with exposed conductive pads, as well as a semiconductor die attached to the substrate second side and having conductive terminals electrically coupled to respective ones of the conductive pads, and a passive component module attached to the second substrate side. The passive component module includes opposite first and second sides, a base extending to the second side, and a redistribution layer structure extending between the base and the first side. The redistribution layer structure includes a passive electronic component with a first component terminal and a second component terminal, a conductive metal trace that forms at least a portion of the passive electronic component, a dielectric layer abutting a portion of the conductive metal trace, a first terminal exposed along the first side and electrically coupled between the first component terminal a first one of the conductive pads of the multilevel package substrate, and a second terminal spaced apart from the first terminal and exposed along the first side, where the second terminal is electrically coupled between the second component terminal and a second one of the conductive pads of the multilevel package substrate.

In a further aspect, a method of fabricating an electronic device comprises forming a redistribution layer structure on a base including: forming a conductive metal trace on the base that forms at least a portion of a passive electronic component having a first component terminal and a second component terminal; forming a dielectric layer abutting a portion of the conductive metal trace; forming a first redistribution layer terminal exposed along a side of the redistribution layer structure and electrically coupled between two first component terminal; and forming a second redistribution layer terminal spaced apart from the first redistribution layer terminal and exposed along the side of the redistribution layer structure, the second redistribution layer terminal electrically coupled to the second component terminal.

### BRIEF DESCRIPTION OF THE DRAWINGS

FIG. 1 is a partial sectional side elevation view of a passive component module with an integrated inductor and capacitor formed in a two level redistribution layer on a shielded base installed on a multilevel package substrate of an electronic device.

FIG. 1A is a sectional top elevation view of the passive component module taken along line 1A-1A of FIG. 1.

FIG. 1B is a partial sectional side elevation view of another passive component module example with bottom side terminals having metal posts or pillars.

FIG. 1C is a partial sectional side elevation view of a further passive component module example with bottom side terminals having solder balls.

FIG. 1D is a partial sectional side elevation view of a system with an electronic device soldered to a host printed circuit board and having a semiconductor die and two passive component modules soldered to a multilevel package substrate and enclosed by a molded package structure.

FIG. 2 is a partial sectional side elevation view of another passive component module with an integrated resistor formed in a single level redistribution layer on a shielded base.

FIG. 2A is a sectional top elevation view of the passive component module taken along line 2A-2A of FIG. 2.

FIG. 3 is a partial sectional side elevation view of another passive component module with an integrated lateral capacitor with interleaved comb plates formed in a three level redistribution layer on a shielded base.

FIG. 3A is a sectional top elevation view of the passive component module taken along line 3A-3A of FIG. 3.

FIG. 4 is a partial sectional side elevation view of another passive component module with an integrated multipole filter circuit with passive inductors and capacitors formed in a two level redistribution layer on a shielded base.

FIG. 5 is a partial sectional side elevation view of further passive component module example with an integrated passive balun formed in a two level redistribution layer on a shielded base.

FIG. 6 is a partial sectional side elevation view of further passive component module example with an integrated transformer formed in a two level redistribution layer on a shielded base.

FIG. 7 is a flow diagram of a method of fabricating an electronic device with a passive component module.

FIGS. 8-21 are partial sectional side elevation views of a passive component substrate module undergoing fabrication processing.

### DETAILED DESCRIPTION

In the drawings, like reference numerals refer to like elements throughout, and the various features are not necessarily drawn to scale. Also, the term “couple” or “couples” includes indirect or direct electrical or mechanical connection or combinations thereof. For example, if a first device couples to or is coupled with a second device, that connection may be through a direct electrical connection, or through an indirect electrical connection via one or more intervening devices and connections. Unless otherwise stated, “about,” “approximately,” or “substantially” preceding a value means +/−10 percent of the stated value. One or more operational characteristics of various circuits, systems and/or components are hereinafter described in the context of functions which in some cases result from configuration and/or interconnection of various structures when circuitry is powered and operating. One or more structures, features, aspects, components, etc. may be referred to herein as first, second, third, etc., such as first and second terminals, first, second, and third, wells, etc., for ease of description in connection with a particular drawing, where such are not to be construed as limiting with respect to the claims. Various disclosed structures and methods of the present disclosure may be beneficially applied to passive components, modules, electronic devices and systems and/or to manufacturing an electronic device such as an integrated circuit. While such examples may be expected to provide various improvements, no particular result is a requirement of the present disclosure unless explicitly recited in a particular claim.

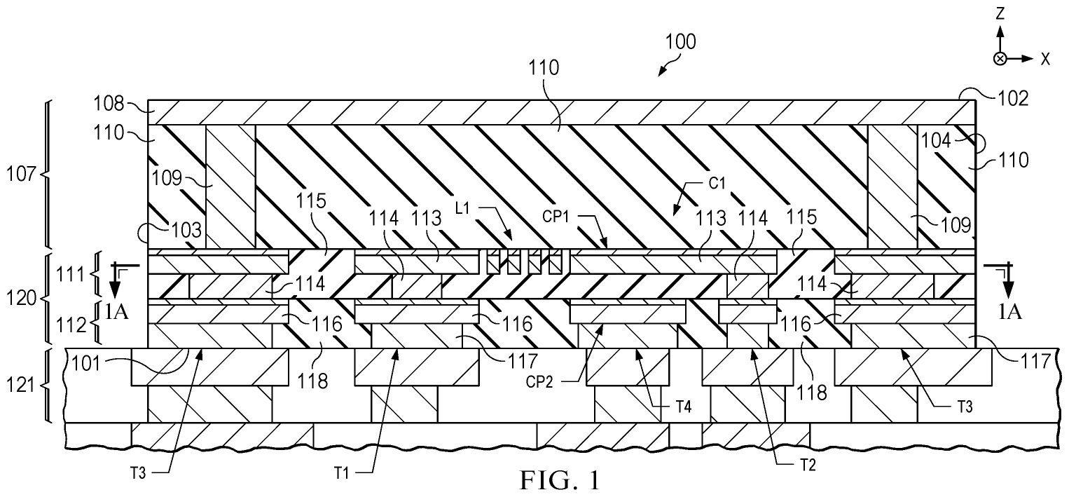

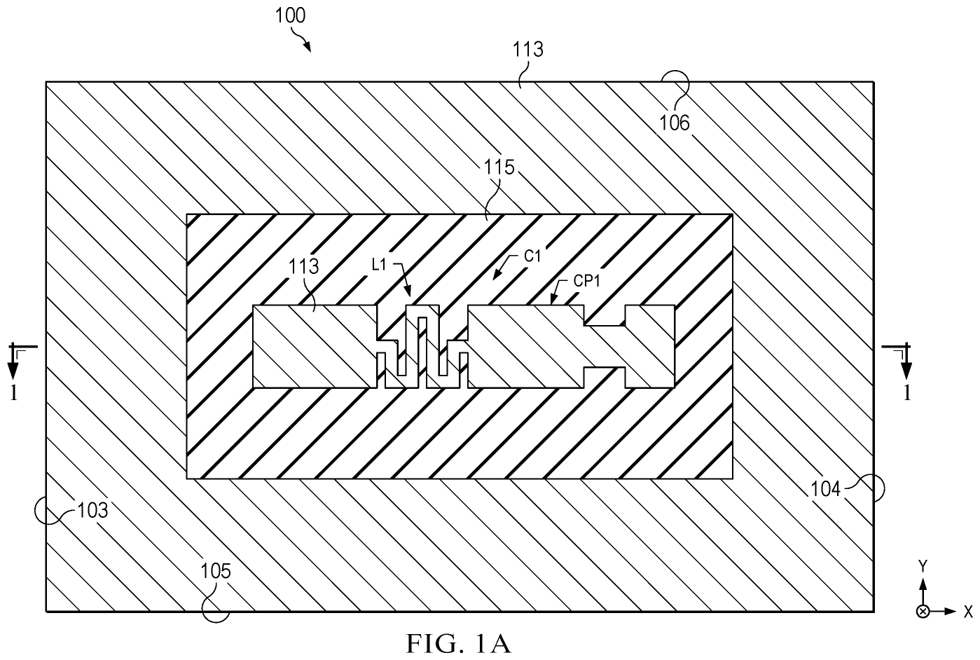

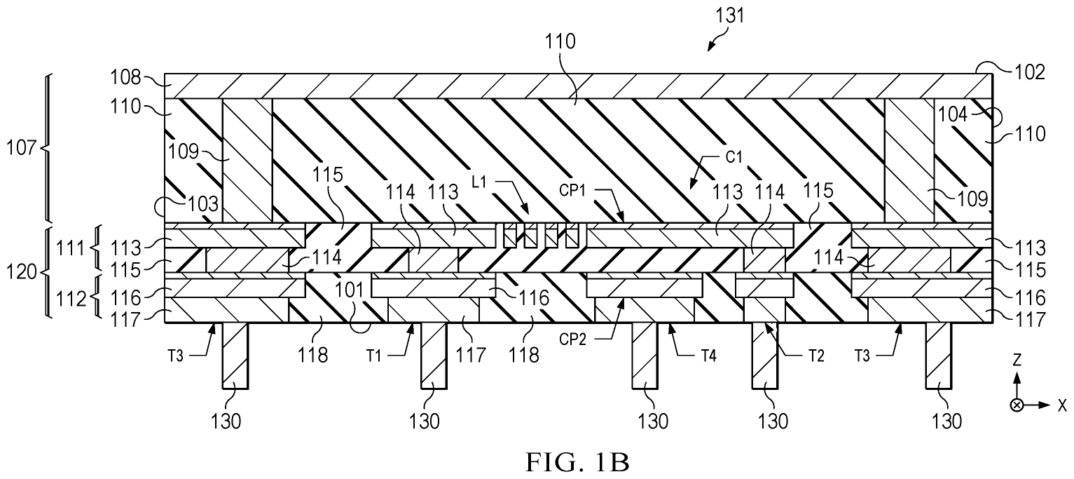

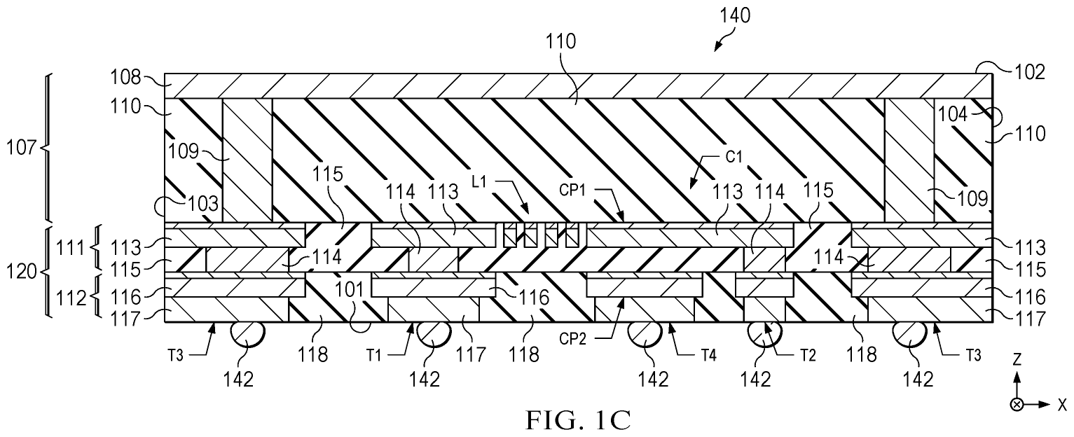

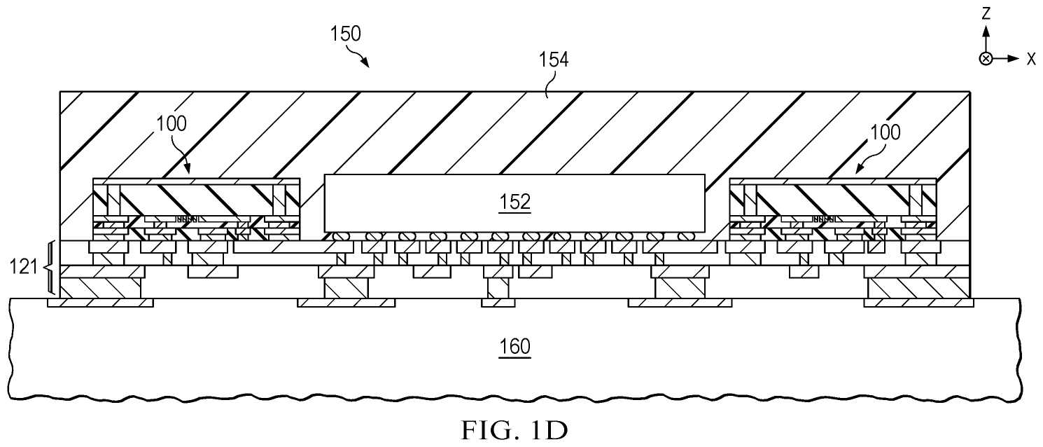

FIGS. 1 and 1A show a passive component module 100 with an integrated inductor L1 and a capacitor C1 of an L-C circuit. FIG. 1A shows a sectional top elevation view of the passive component module 100 taken along line 1A-1A of FIG. 1. The passive component module 100 is shown in an example position or orientation in a three-dimensional space with a first direction X, a perpendicular (orthogonal) second direction Y, and a third direction Z that is perpendicular (orthogonal) to the respective first and second directions X and Y, and structures or features along any two of these directions are orthogonal to one another. The passive component module 100 has opposite first and second (e.g., bottom and top) sides 101 and 102, respectively, which are spaced apart from one another along the third direction Z as shown in FIG. 1. The passive component module 100 also has laterally opposite third and fourth sides 103 and 104 that are spaced apart from one another along the first direction X (FIGS. 1 and 1A), and laterally opposite fifth and sixth sides 105 and 106 (FIG. 1A) that are spaced apart from one another along the second direction Y in the illustrated orientation. The sides 101-106 in one example have substantially planar outer surfaces. In other examples, one or more of the sides 101-106 have curves, angled features, or other non-planar surface features.

As shown in FIG. 1, the passive component module 100 has a base 107 that extends to the second side 102. The base 107 in the illustrated example includes a conductive metal shield having a conductive metal top 108 that extends along the second side 102 and a conductive metal sidewall 109 that extends outward from the conductive metal top 108 (e.g., downward in the orientation of FIG. 1). The base 107 in this example also includes a dielectric structure 110 that extends along the third direction Z between the conductive metal top 108 and a top side of a redistribution layer structure 120. The conductive metal sidewall 109 extends from the conductive metal top 108 to the redistribution layer structure 120. The conductive metal top 108 and the conductive metal sidewall 109 in one example are or include copper, aluminum, or other suitable conductive metal. Any suitable dielectric structure 110 can be used. In one example, the dielectric structure 110 is or includes molding compound formed by compression molding. In another example, the shield 108, 109 can be omitted. The shield structure 108, 109 can help shield one or more passive components of the module 100 from electromagnetic interference (EMI), radio frequency interference (RFI) and other noise. In certain examples, the shield structure is extended downward into the redistribution layer structure 120 and may include bottom side terminal connections to electrically couple the shield to a reference node (e.g., ground) of a host substrate or lead frame to help improve shielding performance.

Any suitable single or multi-level redistribution layer structure 120 with one or more conductive metal traces can be used in various implementations to integrate one or more passive components in an electronic device. The illustrated example is a two level redistribution layer structure 120 with a first level 111 and a second level 112 as shown in FIG. 1. The first level 111 includes a first trace layer 113 with one or more first conductive metal traces. The first level 111 in this example also includes a first via layer 114 with one or more conductive first vias, and a dielectric layer 115. The first trace layer 113 extends between the lower side of the base 107 and the first via layer 114 and includes the one or more conductive metal traces. The first via layer 114 extends between the first trace layer 113 and the first side 101 and the dielectric layer 115 abuts portions of the first trace layer 113 and the first via layer 114. The first level 111 extends along the third direction Z between the base 107 and the second level 112 and the second level 112 extends between the first level 111 and the first side 101.

The second level 112 has a second trace layer 116, a second via layer 117 and a second dielectric 118. The redistribution layer structure 120 extends between the base 107 and the first side 101 of the passive component module 100 along the third direction Z. The second trace layer 116 extends between the first via layer 114 and the second via layer 117, the second via layer 117 extends between the second trace layer 116 and the first side 101 and includes terminals T1-T4, and the second dielectric layer 118 abuts portions of the second trace layer 116 and the second via layer 117.

In this example, the second level 112 of the redistribution layer structure 120 is the final level and includes conductive metal features that form terminals of the module 100 that can be soldered or otherwise electrically interconnected with conductive features of a lead frame, a single or multilevel package substrate, or other suitable structure, such as the package substrate 121 in FIGS. 1 and 1D. In further implementations, the final level of the redistribution layer structure 120 can include metal features that form terminals in combination with copper posts or pillars (e.g., FIG. 1B below) or solder balls (FIG. 1C) to facilitate electrical connection of the module 100 and its terminals to a lead frame or substrate.

The redistribution layer structure 120 includes the passive components inductor L1 and capacitor C1, each of which having first and second component terminals. The passive components L1 and C1 in this example are interconnected in an L-C circuit within the redistribution layer structure 120. The bottom side of the passive component module 100 (e.g., the second level 112) includes exposed conductive features that provide terminal connections for the L-C circuit. In the illustrated example, the first level 111 has a first conductive metal trace 113 that forms at least a portion of the inductor L1, including a serpentine inductor trace best shown in FIG. 1A. In this example, a first inductor component terminal is electrically coupled to a conductive second via 117 of the second level 112 that forms a first terminal T1 of the passive component module 100. The first terminal T1 of the passive component module 100 is electrically coupled to the first inductor terminal by conductive features of the first and second levels 111 and 112 that are in contact with one another, including a second trace feature 116 of the second level 112, a first via feature 114 of the first level 111, and a first conductive metal trace 113 of the first level 111. The interconnected metal features provide electrical coupling between the bottom side first terminal T1 and the first component terminal of the inductor L1.

The second terminal of the inductor L1 (e.g., the right and of the serpentine conductive feature shown in FIG. 1) is a second conductive metal trace 113 that is contiguous with a first terminal of the capacitor passive component C1. The capacitor C1 in this example is a vertical capacitor structure with a first capacitor plate CP1 that forms a first terminal of the capacitor C1. In this example, the first and second component terminals of the inductor L1 and the first component terminal (e.g., CP1) of the capacitor C1 are formed as a contiguous conductive metal trace of the first level 111. The passive component module 100 includes a second terminal T2 that is electrically coupled to the second component terminal of the inductor L1 and to the first component terminal (e.g., CP1) of the capacitor C1. The second terminal T2 in this example is another second via 117 of the second level 112. The second terminal T2 in this example is coupled to the second component terminal of the inductor L1 by another second conductive trace feature 116 of the second level 112 and another first via 114 of the first level 111. The second terminal T2 provides external access to the circuit node that joins the inductor L1 and the first terminal of the capacitor C1. If no external access to this node is needed in a given design, the second terminal T2 can be omitted.

The final (e.g., second) level 112 of the redistribution layer structure 120 in this example also provides a third terminal T3 (FIG. 1) that is electrically coupled through other conductive trace and via features of the first and second levels 111 and 112 to the bottom of the conductive metal sidewall 109. The redistribution layer structure 120 includes another conductive metal trace 113 that abuts the conductive metal sidewall 109, and the third terminal T3 is spaced apart from the first and second terminals T1 and T2. The third terminal T3 is exposed along the first side 101 and electrically coupled to the other conductive metal trace 113 that abuts the metal sidewall 109 through a corresponding further conductive metal trace feature 116 of the second level 112 and a corresponding further conductive metal via feature 114 of the first level. The third terminal T3 in this example allows electrical connection of the shield structure 108, 109 of the base 107 to one or more conductive features of the substrate 121 (e.g., or a lead frame, not shown) of a packaged electronic device to facilitate shielding of one or more passive components (e.g., L1 a and C1) of the passive component module 100.

The passive component module 100 also includes a fourth terminal T4 in the example of FIGS. 1 and 1A, which is formed as another second conductive via 117 of the second level 112. The fourth terminal T4 provides external electrical connection to the second terminal of the capacitor C1, formed as a bottom second plate CP2 (FIG. 1). In this example, the second capacitor plate CP2 is a further second conductive trace feature 116 of the second level 112 that at least partially overlies and contacts a further second via 117 of the second level 112 to form the fourth terminal T4. A portion of the dielectric layer 115 extends between and abuts a lower portion of the first capacitor plate CP1 and an upper portion of the lower second capacitor plate CP2 to form the capacitor C1 as a vertical capacitor, with the first and second capacitor plates CP1 and CP2 separated by a portion of the dielectric layer 115 of the first level 111. In this example, a first conductive metal trace 113 of the first level 111 forms a first portion of the passive capacitor component C1 and another conductive metal trace 116 of the second trace layer 116 forms a second portion of the passive electronic component C1. In other examples, different types of passive electronic components can be formed partially in two different levels or layers of a redistribution layer structure.

In other examples, a capacitor can include first and second plates formed as different conductive features of a single level or layer of a redistribution layer structure, with the plates abutting and separated by an intervening dielectric. For example, a capacitor (not shown) can be formed as to spaced apart conductive metal trace features 113 of the first level 111 with a portion of the dielectric layer 115 extending between the capacitor plates to form a capacitor, with suitable terminals formed in the same trace layer and/or as respective via features contacting or otherwise electrically coupled to the corresponding capacitor plate features.

In further examples, any suitable type of passive circuit components can be formed by conductive metal features (e.g., trace and/or via features) in a single or multilevel redistribution layer structure, with a bottom level (or a single level) having conductive terminal features exposed along the bottom or first side 101 of the passive component module 100 to allow electrical coupling of one or more component terminals to a lead frame and/or package substrate of an electronic device, including a first terminal (e.g., T1) coupled to one or more component terminals and a second terminal (e.g., T2) spaced apart from the first terminal T1 electrically coupled to another component terminal (e.g., of the same or of a different passive component) and exposed along the first side 101.

In one example, the dielectric structure 110 of the base 107 is or includes compression molded dielectric material and the dielectric layer 115 of the first level 111 includes compression molded dielectric material. In one implementation, the dielectric structure 110 of the base 107 and the dielectric layers 115 and 118 of the passive component module 100 are or include the same mold compound material, which is used for build-up material during fabrication of the module 100. This example provides homogeneity in dielectric material, maintaining the same material properties, providing superior performance.

The passive component module 100 is adapted for integration into larger packages, for example, by forming the terminals T1-T4 as land grid array (LGA) pads (FIGS. 1 and 1A) that can be electrically coupled, for example, by solder connections, to a lead frame and/or a single or multilevel package substrate. FIG. 1 shows one example, in which the passive component module 100 is attached to the multilevel package substrate 121 by solder connections of the terminals T1-T4 to corresponding conductive features on the top side of the substrate 121.

FIG. 1B shows another example passive component module 131 having similarly numbered features as described above in connection with FIGS. 1 and 1A. In this example, the passive component module 131 can be integrated into larger packages by bump redistribution layer techniques such as copper posts or pillars 130 as shown in FIG. 1B. The passive component module 131 includes copper posts 130 formed on and/or attached to one or more second vias 117 of the second level 112, for example, to provide interconnections for the terminals T1-T4 associated with the passive components L1 and C1 and/or for a node or nodes of a circuit that includes one or both of the passive components.

FIG. 1C shows a further example passive component module 140 with similarly numbered features as described above in connection with FIGS. 1 and 1A. In addition, the passive component module 140 includes bottom side terminals (e.g., T1-T4) that have attached solder balls 142 in order to facilitate solder connection of the passive component module 140 to a lead frame or substrate (e.g., substrate 121 in FIGS. 1 and 1D).

FIG. 1D shows an example system with an electronic device 150 soldered to a host printed circuit board 160. The electronic device 150 in this example includes two instances of the above described passive component module 140 with an integrated L-C circuit including the inductor L1 and the capacitor C1 described above in connection with FIGS. 1 and 1A. In this case, the electronic device 150 includes the multilevel package substrate 121 (e.g., also shown in FIG. 1 above) that has a first (e.g., bottom) substrate side with exposed conductive leads and an opposite second (e.g., top) substrate side with exposed conductive pads. The electronic device 150 has a semiconductor die 152 attached to the top side of the substrate 121 with conductive die terminals (e.g., conductive pillars or bumps, solder balls, bond pads, etc.) that are electrically coupled to respective ones of the conductive pads, for example, by solder connections (not shown).

The electronic device 150 in FIG. 1D also includes two instances of the passive component module 100 with their respective terminals (e.g., T1-T4 above) soldered to respective conductive features of the multilevel package substrate 121. The electronic device 150 in this example has a molded package structure 154 that encloses the passive component modules 100, the semiconductor die 152, and portions of the upper side of the multilevel package substrate 121.

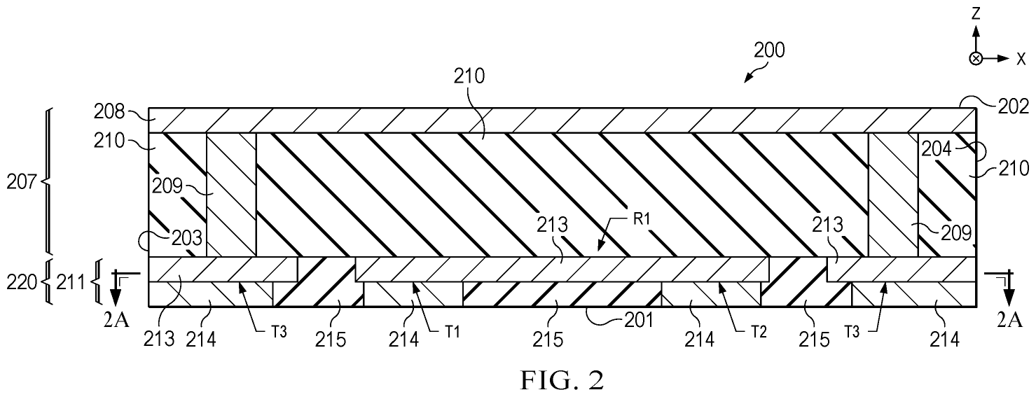

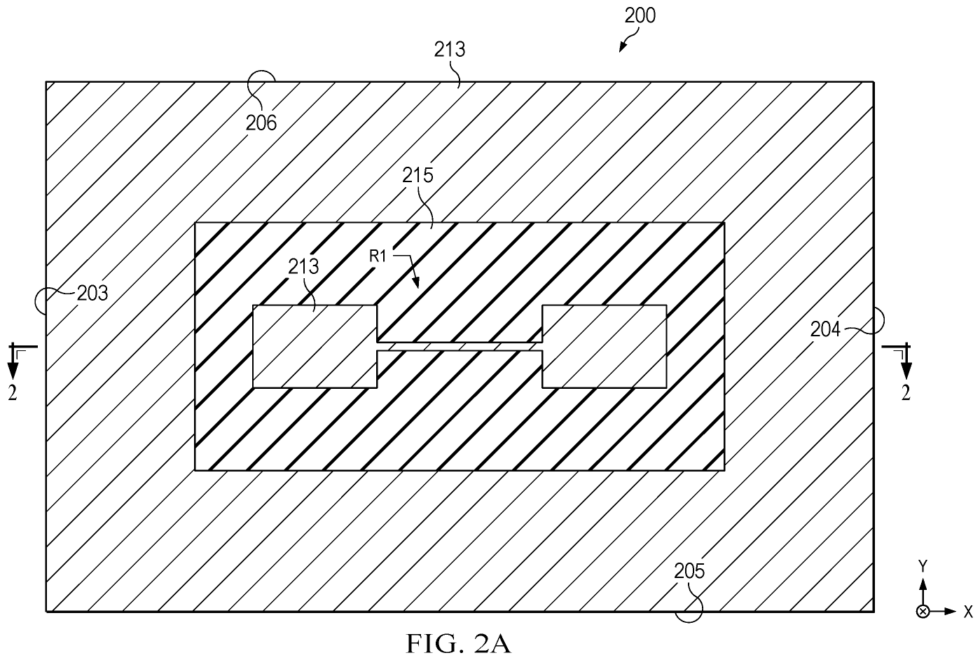

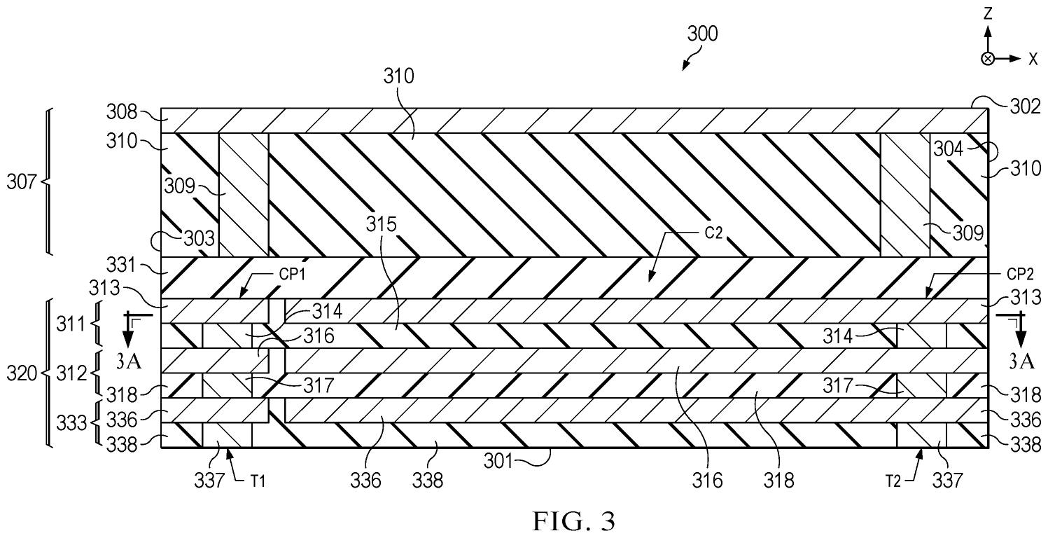

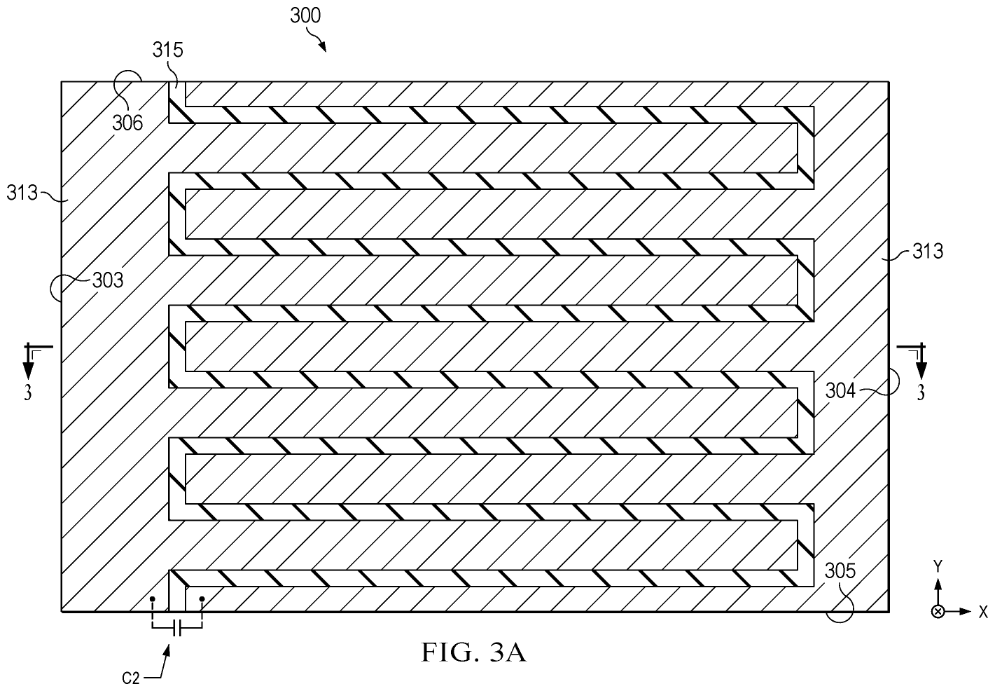

FIGS. 2-6 show further example passive component modules with different types and/or forms of passive circuit components formed at least partially in a single or multilevel redistribution layer structure attached to a base and having a bottom side conductive terminals suitable for electrical coupling (e.g., soldering) to a host lead frame and/or package substrate. The illustrated examples in FIGS. 2-6 include integrated LGA type module terminals on the bottom side. In other implementations, copper pillars and/or solder balls or other terminal types or additional features can be used (e.g., FIGS. 1B and 1C above). The passive component modules in FIGS. 2-6 include a single passive components. In other implementations, more than one of the illustrated passive components and/or other types and sizes of passive components can be integrated within the passive component module. Certain of the passive components can include portions or features formed and multiple levels of a multilevel redistribution layer structure (e.g., FIGS. 3 and 3A below). In other implementations, one or more passive components of a given module design can include features formed in only a single layer or level of a redistribution layer structure.

FIGS. 2 and 2A a show another passive component module 200 with an integrated resistor R1 formed in a single level redistribution layer structure 220 on a shielded base 207. Apart from changes or differences in the patterned conductive features and/or terminal connections of the redistribution layer structure and unless otherwise described hereinafter, the structures, elements, features, etc. 201-210, 211, and 213-215 in one example can generally correspond to the respective structures, elements, features, etc. 101-110, 111, and 113-115 described above in connection with FIGS. 1 and 1A. In this case, however, the patterned conductive features of the redistribution layer structure 220 include a single level 211 with a trace layer and corresponding trace layer features 213, a via layer with corresponding vias 214, and a dielectric layer 215. As best shown in FIG. 2A, one of the conductive trace layer features 213 forms a resistor R1 having first and second (e.g., left and right) resistor component terminals, and an interior or middle portion having a controlled cross sectional area and length to provide a desired amount of electrical resistance between the resistor component terminals.

The single level 211 in this example includes the conductive vias 214 shown in FIG. 2, some of which form first and second resistor connection terminals T1 and T2, and a third terminal T3 coupled to the shield structure 208, 209 of the base 207. The terminals T1-T3 allow solder or other suitable electrical connection of the resistor R1 and the shield of the module 200 to corresponding conductive features of a lead frame or substrate parentheses not shown). In another implementation, the vias 214 and corresponding lower portion of the dielectric 215 can be omitted, and portions of the conductive features 213 of the trace layer of the single level 211 can serve as module terminals T1-T3 for suitable connection of the passive component R1 to a host lead frame or package substrate. The illustrated examples include corresponding redistribution layer structures mounted to shielded bases, including conductive metal shield structures (e.g., 108 and 109) as described above. In yet other implementations, the conductive metal shield features of the base of the passive component module can be omitted.

FIGS. 3 and 3A show another example passive component module 300 with an integrated lateral capacitor (e.g., designated C2 in FIG. 3A) with interleaved comb plates CP1 and CP2 formed in a three level redistribution layer on a shielded base 307. Apart from changes or differences in the patterned conductive features and/or terminal connections of the redistribution layer structure and unless otherwise described hereinafter, the structures, elements, features, etc. 301-318 in one example can generally correspond to the respective structures, elements, features, etc. 101-118 described above in connection with FIGS. 1 and 1A. The passive component module 300 in FIGS. 3 and 3A includes an integrated lateral capacitor C2 with interleaved comb plates formed in respective conductive trace layers of each level of a three level redistribution layer structure 320 on the shielded base 307.

A first capacitor plate CP1 of the capacitor C2 (e.g., extending all the way to the left in FIG. 3A) has a comb shape that includes a set of first left-facing fingers, and the second capacitor plate CP2 (e.g., extending all the way to the right in FIG. 3A) a set of second right-facing fingers that are interleaved with the first fingers of the first capacitor plate CP1. As shown in FIG. 3, the interleaved comb shapes of the first and second capacitor plates in this example are reproduced in the respective trace layers 313 and 316 of each of the first and second levels 311 and 312 as well as in third trace layer features 336 of a third level 333.

The final (e.g., third) level 333 in this example includes a third conductive metal via structures 337 exposed along the bottom or first side 301 of the module 300. The third level 333 includes a third dielectric layer 338 that extends around and between the third conductive metal trace features 336 and via features 337 except for the exposed terminals T1 and T2 along the bottom or first side 301. The fingers of the capacitor plates CP1 and CP2 are spaced apart from one another and separated by the corresponding third dielectric layer 338. The passive component module 300 in one example includes an optional dielectric spacer layer 331 shown in FIG. 3. The spacer layer 331 can help provide or enhance electrical isolation between the conductive metal sidewall feature 309 of the shield of the base 307, for example, where the capacitor plates extend to the lateral sides 303 and 304 of the passive component module 300. In another implementation, the dielectric spacer layer 331 can be omitted, and the structure of the first conductive metal trace features 313 of the first level 311 can be changed such that the capacitor plates are electrically isolated from any included shield structure of the base 307.

In another example implementation (not shown), a lateral capacitor can be formed by any suitable laterally spaced first and second conductive metal features of a redistribution layer structure that are formed in a single trace layer or single level (e.g., with or without a corresponding via layer to form externally solderable terminals T1 and T2) and/or in any other number of two or more levels. For example, a single level 311 can include conductive metal trace features 313 that form two spaced apart capacitor plates with intervening portions of a dielectric layer 315, and portions of bottom sides of the conductive metal trace features 313 can be exposed outside the dielectric layer 318 to provide solderable terminals T1 and T2 for connection of the resulting capacitor to a host lead frame and/or substrate. Two or more conductive metal vias 314 can be provided with exposed bottom sides in another non-limiting example (not shown).

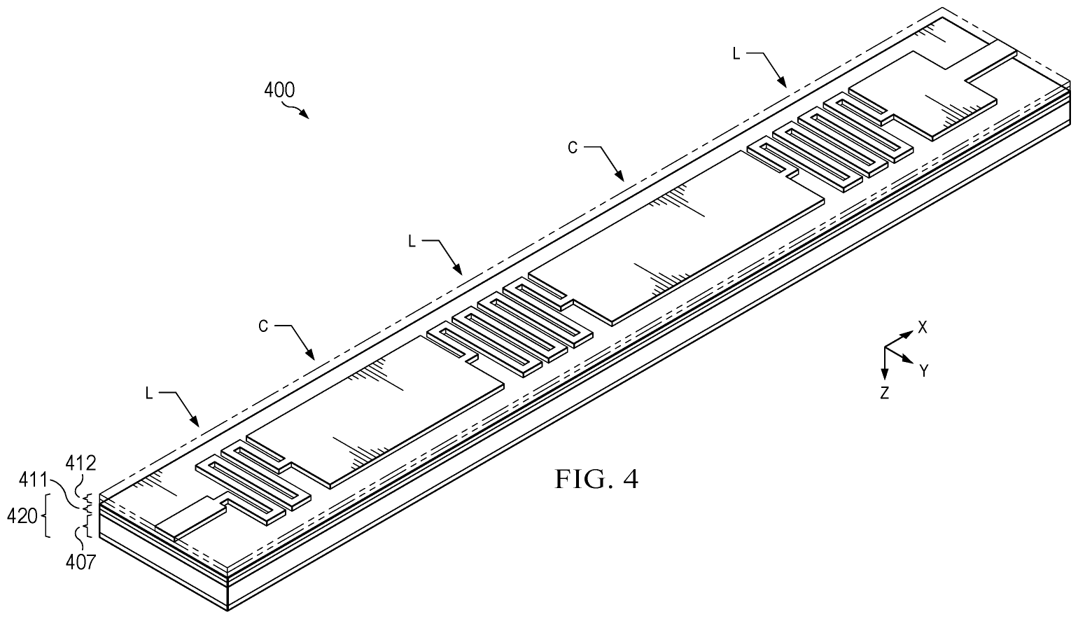

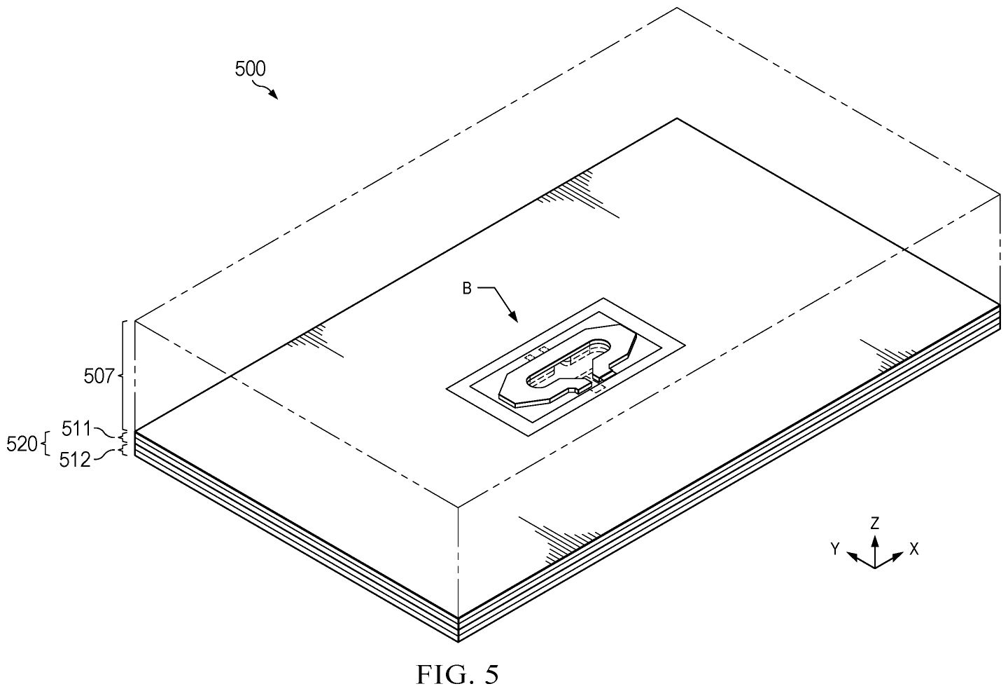

FIGS. 4 and 5 show further non-limiting example passive component modules 400 and 500 that respectively illustrate L-C-L-C-L filter and balun examples. Apart from changes or differences in the patterned conductive features and/or terminal connections of the redistribution layer structure and unless otherwise described hereinafter, the structures, elements, features, etc. L, C, 407, 411, 412, and 420 in one example of the passive component module 400 in FIG. 4 can generally correspond to the respective structures, elements, features, etc. L1, C1, 107, 111, 112, and 120 described above in connection with FIGS. 1 and 1A. The example passive component module 400 in FIG. 4 includes a filter circuit with passive inductors L and capacitors C formed in a two level redistribution layer structure 420 on a shielded base 407.

The example passive component module 500 in FIG. 5 has an integrated passive balun B formed in a two level redistribution layer structure 520 with a first level 511 and a second level 512 on a shielded base 507. Apart from changes or differences in the patterned conductive features and/or terminal connections of the redistribution layer structure 520 and unless otherwise described hereinafter, the structures, elements, features, etc. 507, 511, 512, and 520 in one example of the passive component module 500 in FIG. 5 can generally correspond to the respective structures, elements, features, etc. 107, 111, 112, and 120 described above in connection with FIGS. 1 and 1A.

FIG. 6 shows a further non-limiting example passive component module 600 that includes a transformer T integrated in respective first and second levels 511 and 512 of a two level redistribution layer structure 520 formed on a shielded or on shielded base 507. Apart from changes or differences in the patterned conductive features and/or terminal connections of the redistribution layer structure and unless otherwise described hereinafter, the structures, elements, features, etc. 607, 611, 612, and 620 in one example of the passive component module 600 in FIG. 6 can generally correspond to the respective structures, elements, features, etc. 107, 111, 112, and 120 described above in connection with FIGS. 1 and 1A. The example passive component module 600 in FIG. 6 includes an integrated transformer formed in a two level redistribution layer structure on a shielded base. In other implementations, primary and secondary windings and corresponding routing and terminal connections can be constructed in a single or multiple level redistribution layer structure to create a transformer.

Other examples can include one or more of the above described types and forms of passive electronic circuit components integrated into a single or multiple level redistribution layer structure attached to a shielded or on shielded base, including without limitation one or more resistors, capacitors, inductors, balance, resistors, diodes, transformers, etc. The integration of one or more passive circuit components in a passive component module can facilitate cost effective casy integration of one or more passive circuit elements in a packaged electronic device without consuming additional die area and without changing lead frame and/or single or multilevel package substrate designs, particularly as compared with integrating passive components on individual semiconductor dies. In addition, the illustrated examples can advantageously provide lower cost and potentially smaller passive components compared with package level mounting and interconnection of surface mount technology (SMT) passive circuit components on a lead frame and/or package substrate.

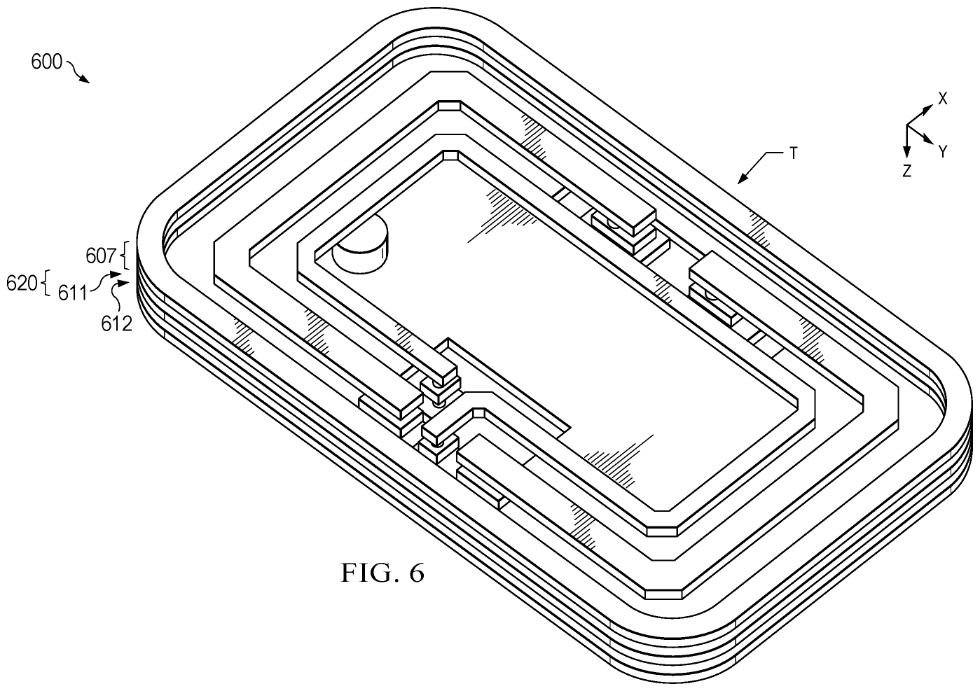

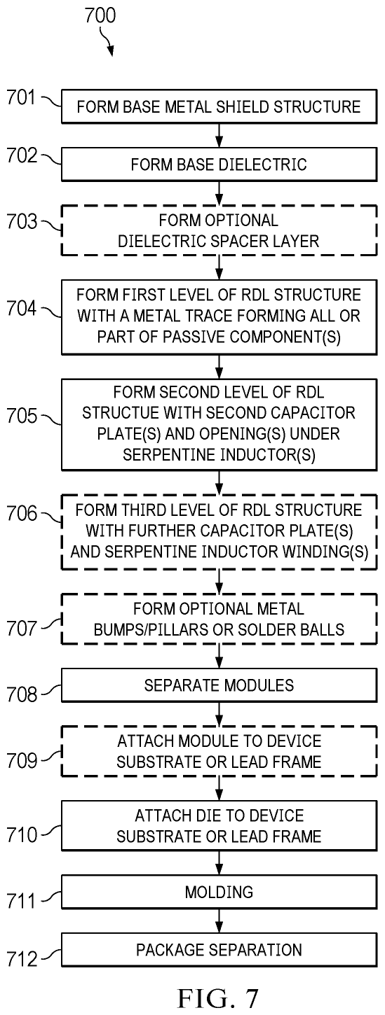

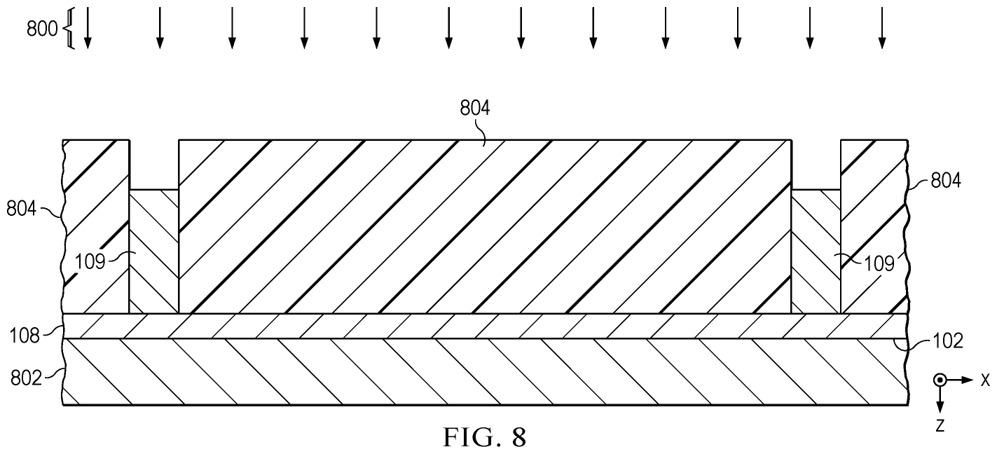

Referring also to FIGS. 7-21, the illustrated examples also provide advantages and benefits with respect to manufacturing costs compared to SMT passive component integration and/or die level passive component integration. FIG. 7 shows an example method 700 for fabricating an electronic device with a passive component module, and FIGS. 8-21 show the example electronic device 150 of FIG. 1D and instances of the included example passive component module 100 of FIGS. 1 and 1A undergoing fabrication processing according to the method 700. In one implementation of the method 700, redistribution layer and/or multilevel package substrate construction and fabrication processing techniques and equipment can be used to fabricate the passive component module 100 and conventional electronic device packaging processes and equipment can be used to integrate one or more passive component modules 100 into the finished packaged electronic device 150. Similar techniques can be used for integration of other passive component types and/or forms, including without limitation the examples of FIGS. 2-6 above and alternatives thereof into a finished packaged electronic device.

The method 700 begins at 701-703 in FIG. 7 with fabrication or construction of the base 107. Multiple bases 107 can be concurrently constructed in one example is individual unit areas of a panel array having rows and columns of unit areas, which can be separated from one another after base formation and/or after redistribution layer processing to provide individual bases 107 and/or individual finished passive component modules 100.

At 701, the method 700 includes forming a base metal shield structure. FIG. 8 shows an example including a conductive metal carrier or base structure 802 with the conductive metal top 108 formed as a layer on the carrier 802. In one implementation, the conductive metal top 108 is formed by performing a deposition process (not shown) that deposits or otherwise forms the conductive metal top 108 on the carrier 802. The illustrated example also includes performing an electroplating process 800 as shown in FIG. 8 using a plating mask 804 to form the conductive metal sidewall 109 that extends from the conductive metal top 108 (e.g., upward along the third direction Z in the orientation shown in FIG. 8).

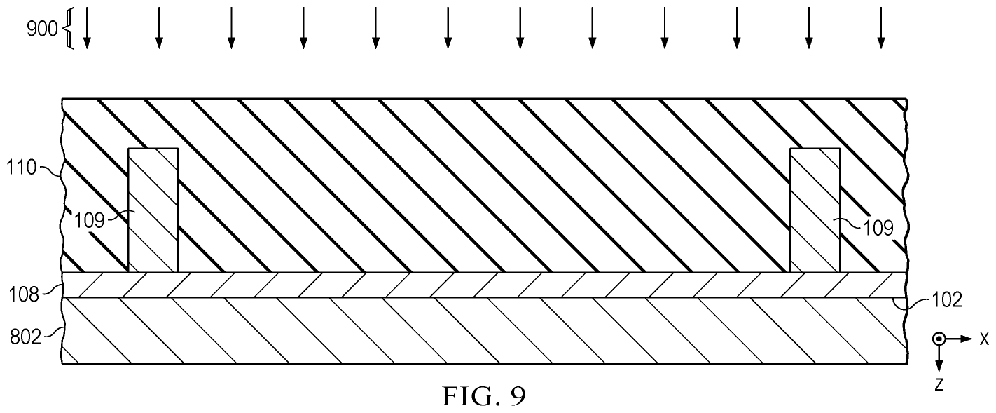

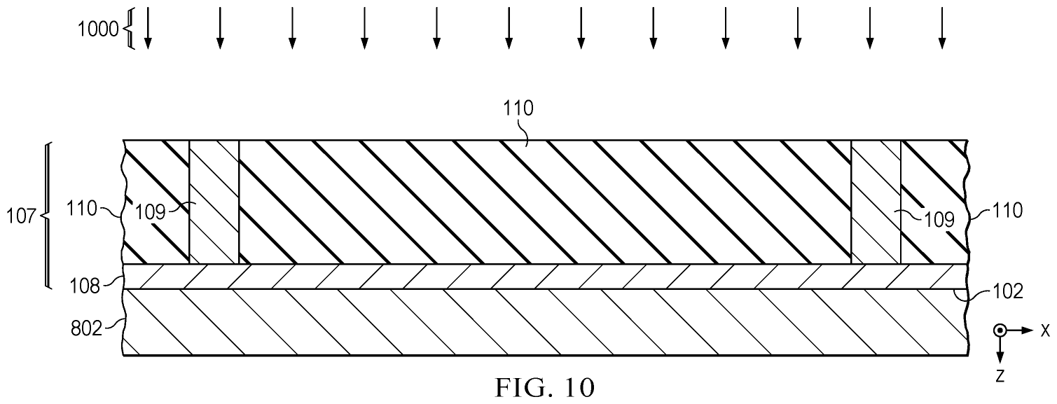

The method 700 continues at 702 and FIG. 7 with forming the base dielectric. FIGS. 9 and 10 show one example, in which a deposition process 900 deposits the dielectric structure 110 over the conductive metal top 108 and the conductive metal sidewall 109. In one example, the deposition process 900 is a compression molding process that includes depositing and pressurizing fine-grained particulate mold compound over the metal top 108 and the conductive metal sidewall 109. In this example, the deposited dielectric structure 110 extends past the ends of the metal sidewall 109, and the resulting structures are then planarized. FIG. 10 shows one example, in which a planarizing process 1000 is performed that exposes a portion of the conductive metal sidewall 109 through the dielectric structure 110 along a side of the base 107.

The method 700 and FIG. 7 continues with single or multiple level redistribution layer fabrication processing at 704-706. In one example, the redistribution layer processing can be the same or similar to that used in constructing redistribution layer is on semiconductor dies and/or wafers, with the redistribution layer or layers being formed on the base 107 instead of a starting semiconductor die or wafer. For example, the redistribution layer structure 120 can be constructed using processes and equipment that are the same or similar to those associated with chip-first fan-out packaging technology. The example of FIG. 7 includes processing at 704 to form a first level as well as processing at 705 to form a second level and optional processing at 706 to form a third level. In other implementations, only a single level may be needed, or a different integer number of levels can be constructed.

In one example implementation, the method 700 can include forming an optional dielectric spacer layer at 703 in FIG. 7, for example, where electrical isolation of any included base shield structure from the redistribution layer structure is desired (e.g., dielectric spacer layer 331 in FIG. 3 above). Where a shield is provided in the base 107, and electrical connections are desired, the formation of the optional dielectric spacer layer at 703 can be omitted, as in the illustrated example of FIGS. 8-21.

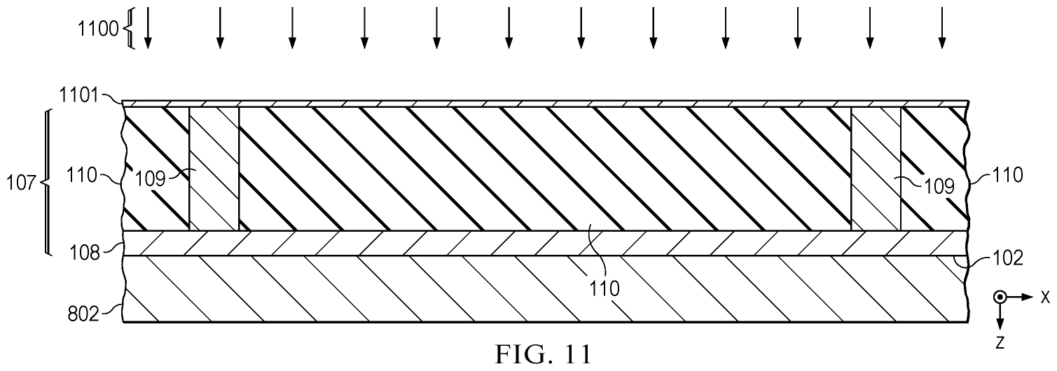

At 704 in FIG. 7, the example implementation of the method 700 includes forming a first level of a redistribution layer (e.g., R DL) structure with a metal trace forming all or part of one or more passive electronic circuit components. FIGS. 11-15 show one example, in which the first level 111 is fabricated to include the above-described first trace layer 113, first via layer 114 and first dielectric layer 115. As previously discussed, certain passive component modules may not need a first via layer 114, for example, to form a passive circuit component in a single trace layer (e.g., lateral capacitor, resistor, inductor, etc.). The illustrated example includes conductive metal features formed by electroplating which are or include copper. In other implementations, a different conductive metal can be used, such as aluminum or metals that include aluminum, etc.

FIG. 11 shows one example, in which a copper or other suitable metal seed layer 1101 is deposited on the illustrated side of the dielectric structure 110 and any included conductive metal sidewall 109 of the base 107, for example, by a sputtering, vapor deposition or other suitable deposition process 1100. The seed layer 1101 can facilitate subsequent patterned electroplating to form the conductive metal features 113 and 114 of the first level 111. In other implementations, the seed layer 1101 can be omitted and other techniques can be used to form patterned conductive features by electroplating or other suitable deposition and/or patterning steps (not shown). The seed layer 1101 in the illustrated example is formed by a blanket deposition process 1100 such as chemical vapor deposition (CVD) on the bottom side of the base 107 including the exposed portions of the dielectric structure 110 and the conductive metal sidewalls 109 to facilitate subsequent electroplating. Alterations or variations of the patterned conductive metal features (e.g., 113) of the various levels and/or layers can be accommodated by changes to the electroplating masks used in the illustrated implementation of the method 700.

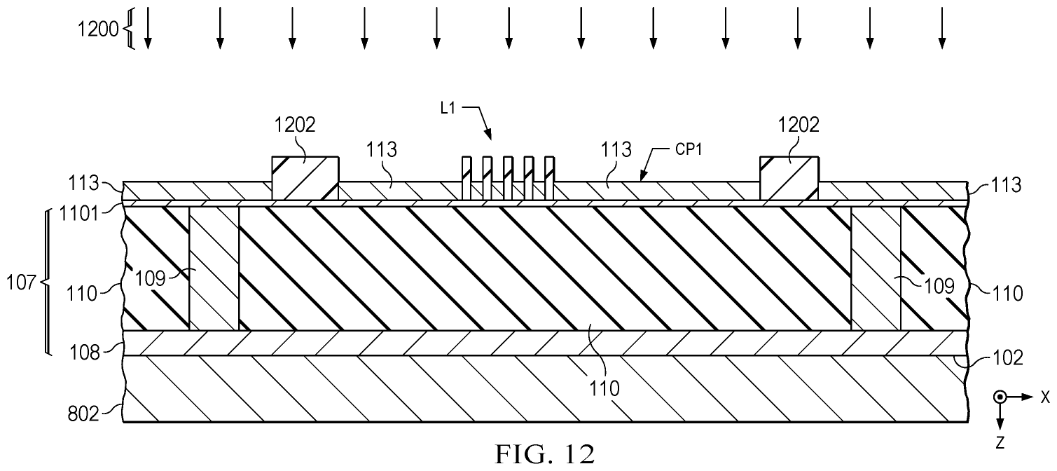

In FIG. 12, an electroplating process 1200 is performed using a plating mask 1202 that forms the first conductive metal trace 113 and its patterned features on the seed layer 1101 of the base 107. The electroplating process 1200 deposits copper onto the portions of the example seed layer 1101 exposed through openings in the plating mask 1202 in order to form the first conductive metal trace layer 113 that forms at least a portion of the passive electronic component. The first trace layer 113 in this example includes the inductor L1 and the first capacitor plate CP1 of the capacitor C described above in connection with FIGS. 1 and 1A on the included copper seed layer 1101 over the dielectric structure 110 along the side of the base 107. In addition, the example electroplating process 1200 forms a second conductive metal trace 113 that abuts a portion of the conductive metal sidewall 109 along the side of the base 107, for example, where extension of the conductive metal shield through the resulting redistribution layer structure 120 is desired.

In one example, where no via layer 114 is to be constructed, the first plating mask 1202 is removed, any included remnant copper seed layer material 1101 between the patterned conductive metal trace features 113 is removed by etching, and the finished passive component module can be separated from other modules of the starting rows and columns of the panel array.

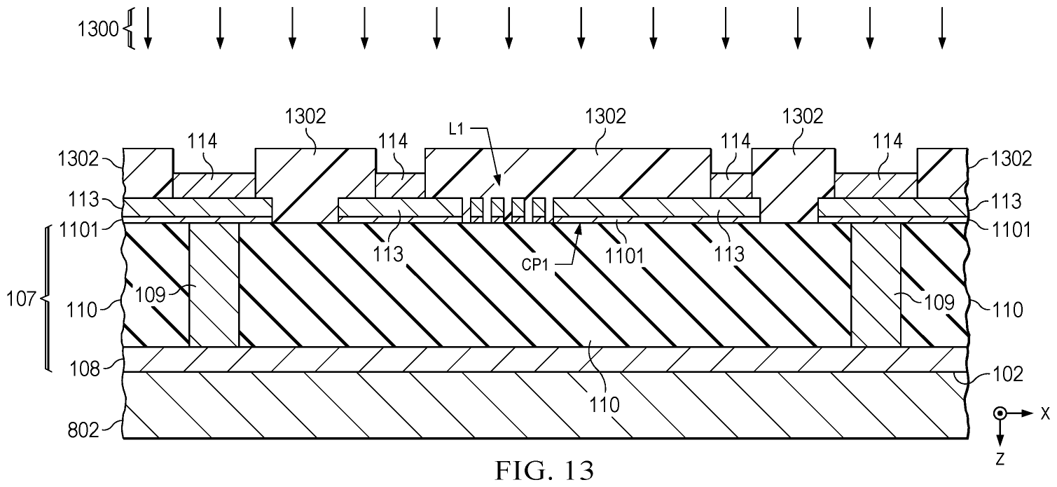

In the illustrated example, the first plating mask 1202 is removed, and a second electroplating process 1300 is performed with a second plating mask 1302 as shown in FIG. 13. The electroplating process 1300 in this example forms the first via layer with the desired patterned vias 114 as shown in FIG. 13. In one implementation, the second plating mask 1302 is then removed and a copper etch process is performed (not shown) that removes any remaining portions of the included copper seed layer 1101 between the patterned conductive metal trace features 113 of the first trace layer.

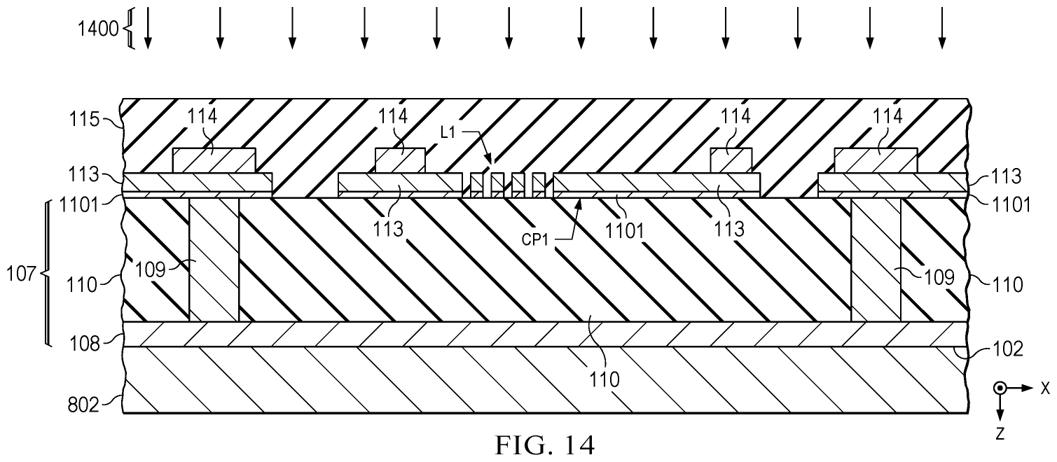

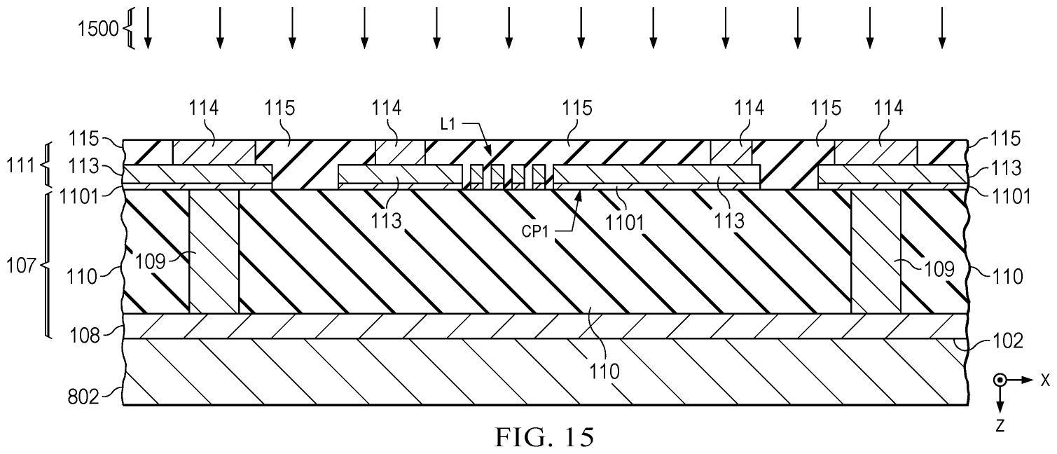

FIGS. 14 and 15 show formation of the first compression molded dielectric layer features 115 in the first level 111 of the example multilevel redistribution layer structure 120. A compression molding process 1400 is performed in FIG. 14 to form the molded dielectric layer features 115 on exposed portions of the metal features of the first traces 113 and the copper metal vias 114 of the first level 111. In one implementation, the compression molding process 1400 uses the same materials as used in forming the dielectric structure 110 of the base 107 and includes depositing and pressurizing fine-grained particulate mold compound over the exposed portions of the first conductive metal traces 113, the first conductive metal vias 114 and any exposed portion of the base dielectric structure 110. In the example of FIG. 14, the deposited dielectric structure 115 extends past the ends of the first vias 114, and the resulting structures are then planarized. In other implementations, a different dielectric layer formation process can be used, such as a deposition process (not shown). The compression molding process 1400 forms the molded dielectric layer features 115 in FIG. 14 to an initial thickness that covers the first traces 113 and the copper metal vias 114.

A grinding process 1500 is performed in FIG. 15, which grinds upper portions of the molded dielectric material 115 and exposes the upper portions of the first vias 114. In another example, a chemical etch is used. In a further example, a chemical mechanical polishing (CMP) process is used. As shown in FIG. 15, the first dielectric layer 115 encloses a portion of the first traces 113 and side portions of the conductive metal vias 114, and the first level 111 as described above in connection with FIGS. 1 and 1A is completed.

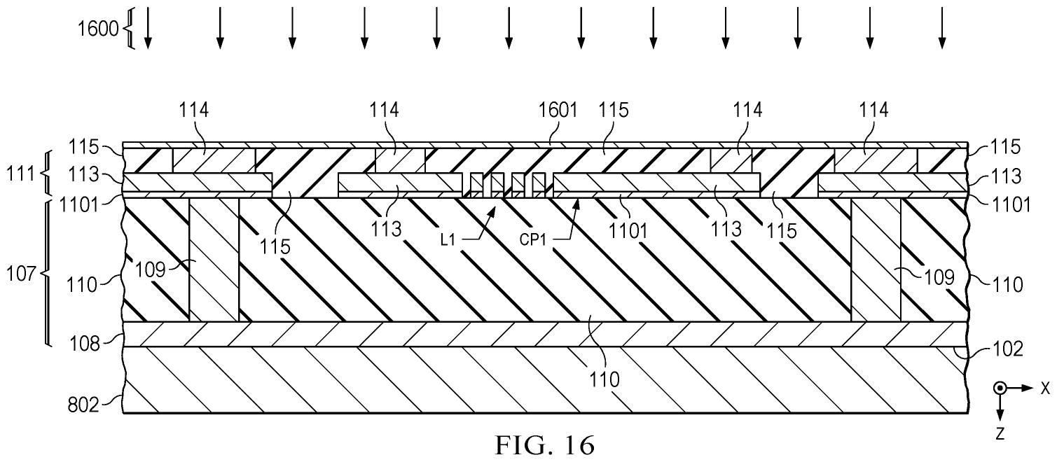

The method 700 continues at 705 in FIG. 7 to form the second level 112 of the redistribution layer structure 120. FIGS. 16-20 show one example, in which the second level 112 is fabricated on the first level 111 to include the above-described second trace layer 116, second via layer 117 and second dielectric layer 118. Some passive component module designs may not need a second via layer 117. FIG. 16 shows one example, in which a second copper seed layer 1601 is deposited on the illustrated side of the first level 111, for example, by a sputtering, vapor deposition (e.g., blanket CVD deposition) or other suitable deposition process 1600. In other implementations, the second seed layer 1601 can be omitted and other techniques can be used to form patterned conductive features by electroplating or other suitable deposition and/or patterning steps (not shown).

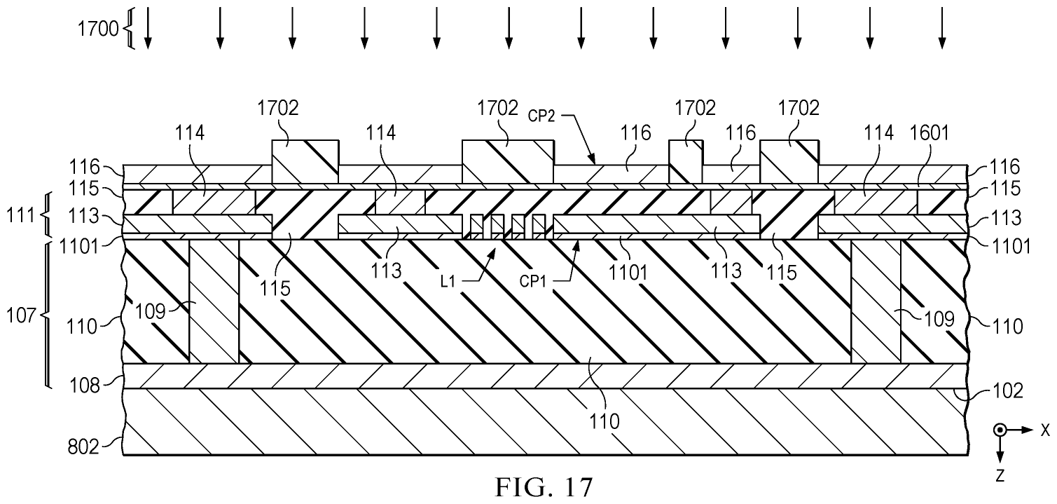

As shown in FIG. 17, an electroplating process 1700 is performed using a plating mask 1702 that forms the second conductive metal trace 116 and its patterned features on the seed layer 1601. The electroplating process 1700 deposits copper onto the portions of the second seed layer 1601 that are exposed through openings in the plating mask 1702 in order to form the second conductive metal trace layer 116 that forms at least a portion of the passive electronic component. The second trace layer 116 in this example includes the lower or second capacitor plate CP2 of the capacitor C described above in connection with FIGS. 1 and 1A. In addition, the example electroplating process 1700 forms another conductive metal trace 116 that abuts a portion of a first via 114 that is electrically coupled to the conductive metal sidewall 109 to extend the conductive metal shield through the second level 212 of the redistribution layer structure 120.

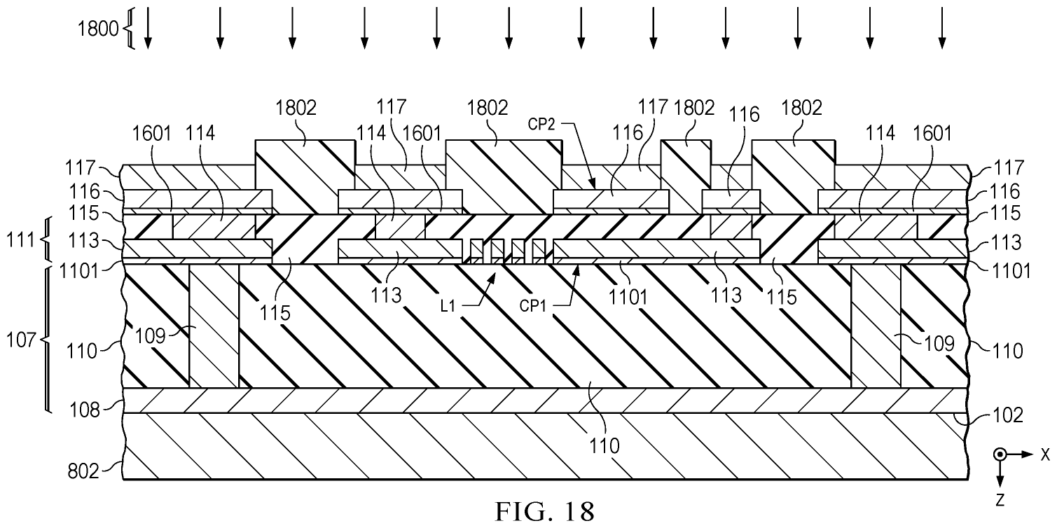

The plating mask 1702 is removed, and a further electroplating process 1800 is performed with another plating mask 1802 as shown in FIG. 18. The electroplating process 1800 in this example forms the second via layer with the desired patterned vias 117 as shown in FIG. 18. In one implementation, the second plating mask 1802 is then removed and a copper etch process is performed (not shown) that removes any remaining portions of the copper seed layer 1601 between the patterned conductive metal trace features 116 of the second trace layer.

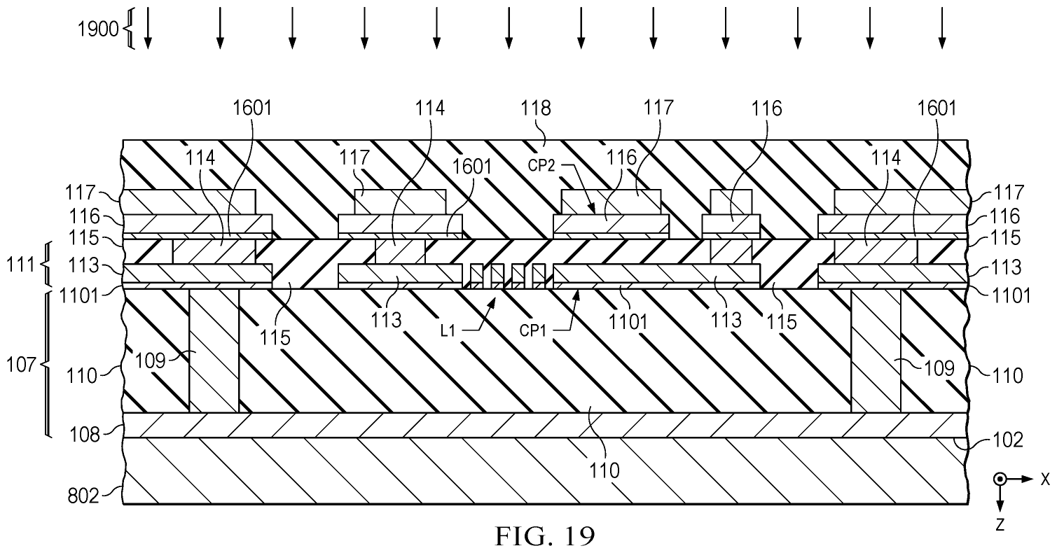

A compression molding process 1900 is performed in FIG. 19 to form the molded dielectric layer features 118 on exposed portions of the metal features of the second traces 116 and the copper metal vias 117 of the second level 112. In one implementation, the compression molding process 1900 uses the same materials as used in forming the dielectric structure 110 of the base 107 and the first dielectric layer 115 of the first level 111. This example includes depositing and pressurizing fine-grained particulate mold compound over the exposed portions of the second conductive metal traces 116, the second conductive metal vias 117 and any exposed portion of the first level 111. The example deposited dielectric structure 118 extends past the ends of the metal second conductive vias 117.

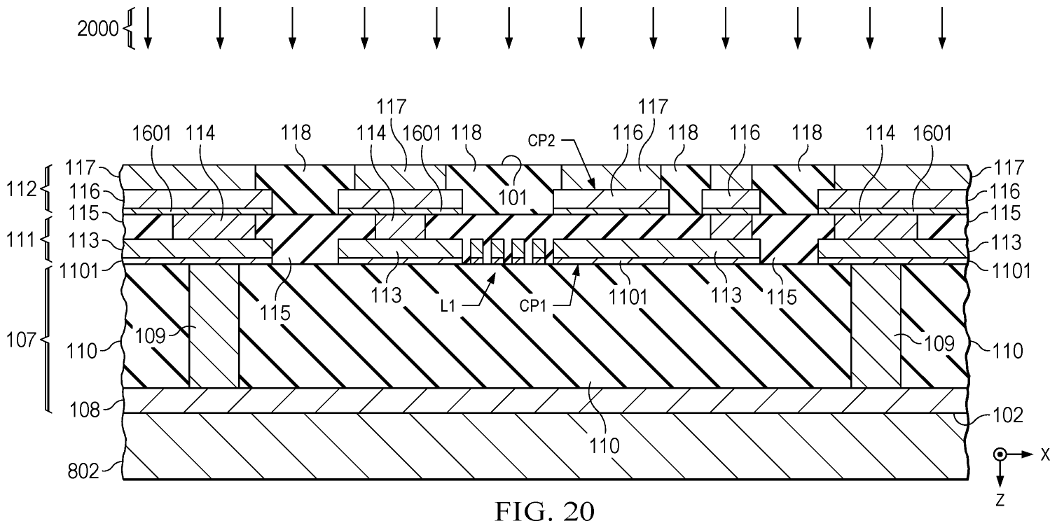

The extra portion of the compression molded dielectric material 118 is then planarized by performing a grinding process 2000 in FIG. 20. The process 2000 grinds upper portions of the molded dielectric material 118 and exposes the upper portions of the second vias 117. In another example, a chemical etch is used. In a further example, a chemical mechanical polishing (CMP) process is used. As shown in FIG. 20, the second dielectric layer 118 encloses a portion of the second traces 116 and side portions of the conductive metal vias 117, and the second level 112 as described above in connection with FIGS. 1 and 1A is completed.

For designs having further redistribution layer structure levels (e.g., FIGS. 3 and 3A above), the method continues at 706 in FIG. 7 to form a third and possibly further levels, for example, using similar processing steps as described above in connection with FIGS. 16-20. In certain examples, the method 700 includes forming optional conductive metal pillars or bumps or solder balls at 707 (e.g., copper pillars 130 in FIG. 1B or solder balls 142 in FIG. 1C above).

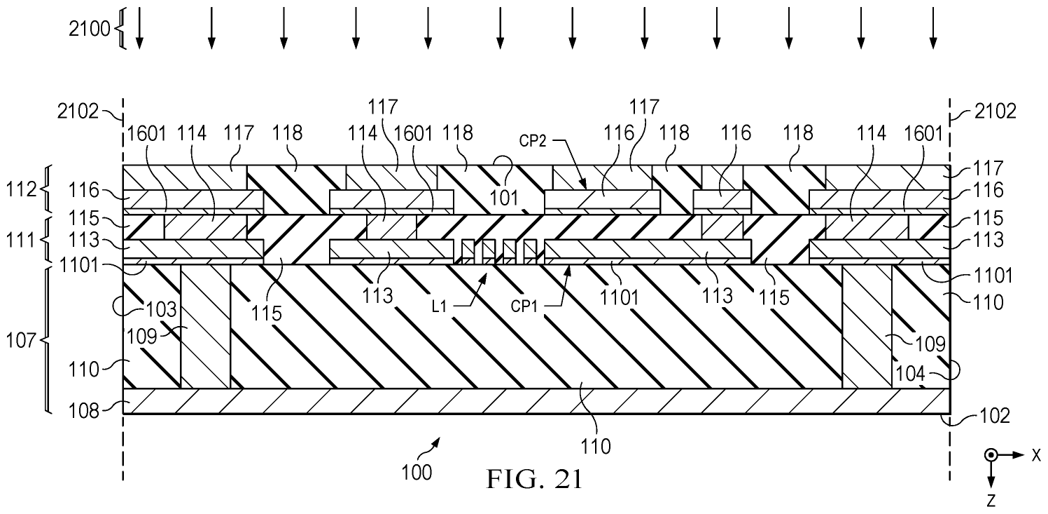

In one implementation, where multiple passive component modules are concurrently fabricated in rows and columns of a panel array structure (not shown), the method 700 can include separating individual modules at 708 (e.g., passive component module 100) from other similar modules of the starting array structure. FIG. 21 shows one example, in which a saw cutting or other separation process 2100 is performed that separates the individual passive component modules 100 from the starting panel array structure along lines 2102. Any suitable separation processing tools and techniques can be used, including without limitation saw cutting, laser cutting, etching processes, or combinations thereof.

The illustrated method 700 in FIG. 7 includes further processing at 709-712 to use one or more instances of the passive component module 100 to form a packaged electronic device (e.g., electronic device 150 in FIG. 1D above). At 709, the method 700 includes attaching one or more instances of the passive component module 100 to a device substrate or lead frame. For example, the module attachment at 709 can include automated pick and place equipment (not shown) used to place individual passive component modules 100 in corresponding unit areas of a starting lead frame panel array and/or a starting single or multilevel package substrate having rows and columns of unit areas. The attachment at 709 includes electrical connection of the terminals (e.g., T1-T4) of the passive component module 100 to corresponding conductive features of the unit arca (e.g., lead frame conductive metal features, single or multilevel package substrate conductive features, etc.). In one example, conductive solder paste is selectively applied to select portions of the target lead frame or substrate, for example, by any suitable printing, dispensing, silk-screening process, followed by automatic placement of the passive component modules 100 in the appropriate locations.

In the illustrated example, moreover, the method 700 includes die attachment at 710 to attach one or more semiconductor dies (e.g., die 152 in FIG. 1D) to appropriate positions of the lead frame or substrate. A single process can be used for the module attachment at 709 and the die attachment at 710, or separate processes can be used. The attachment processing in one example also includes reflow processing (not shown) to reflow the solder paste and form mechanical and electrical interconnections between the conductive metal terminals T1-T4 of the individual passive component modules 100 and the corresponding conductive features of the lead frame or substrate, and to likewise reflow solder associated with any attached semiconductor dies 152.

The method 700 continues at 711 in FIG. 7 with molding or other enclosure processing. In one example, the molding at 711 forms the molded package structure 154 shown in FIG. 1D above that encloses the passive component modules 100, the semiconductor die 152 and portions of the top side of the host substrate 121.

At 712 in FIG. 7, the method 700 in one example includes package separation processing. In one example, the package separation at 712 includes saw cutting to cut through portions of the molded package structure and possibly to separate unit area portions of a starting lead frame or substrate panel array from one another to provide individually separated packaged electronic devices, such as the electronic device 150 shown above in FIG. 1D.

The described examples facilitate incorporation or other integration of passive circuit elements or components into packaged electronic devices while avoiding or mitigating the shortcomings of die/wafer level passive component integration and/or incorporation of surface mount technology passive components into a device package. This allows a wide variety of integration possibilities without having to change wafer fabrication processes or host lead frame/multilevel package substrate designs. Moreover, the cost of fabricating the passive component modules can be significantly less than that of obtaining surface mount technology components and can also save significant device package area to facilitate further reduction in the electronic device sizes. Described examples provide examples of the possible benefits in a variety of circuit applications with cost effective manufacturing methodology to enable the design of self-contained miniaturized passive component modules (e.g., capacitors, inductor coils, filters, resistors, balance, transformers, diodes, etc. or combinations thereof) using package level redistribution layer construction techniques the same as or similar to chip-first-fan-out technology. In addition, certain examples provide advantages and benefits with respect to EMI and/or RFI or other noise sources by providing integrated shielding for the passive component to help improve product performance.

Moreover, manufacturing efficiency and device performance improvements can be achieved by advantageous use of a single type of dielectric material (e.g., fine granule mold compound) used for build-up material in a layer by layer approach as described above in connection with FIG. 7-21 to achieve an integrated module structure with the same-based dielectric material to reduce cost and process complexity as well as facilitate dielectric material homogeneity, with little or no difference in coefficient of thermal expansion (CTE) in the different layers or levels of the passive component module and provide thermal performance benefits compared with other approaches. The described examples and variants thereof can provide benefits in terms of cost savings compared with purchasing individual discrete SMT components, as well as savings and silicon area by taking passive components off the semiconductor wafers and instead and integrating in package. The integration of passive components in the redistribution layer structure 120 also facilitates easy customization of passive components.

Modifications are possible in the described examples, and other implementations are possible, within the scope of the claims.

What is claimed is:

1. A passive component module, comprising:
opposite first and second sides;
a base extending to the second side; and
a redistribution layer structure extending between the base and the first side, the redistribution layer structure including:
a passive electronic component with a first component terminal and a second component terminal;
a conductive metal trace that forms at least a portion of the passive electronic component;
a dielectric layer abutting a portion of the conductive metal trace;
a first terminal exposed along the first side and electrically coupled to the first component terminal; and
a second terminal spaced apart from the first terminal and exposed along the first side, the second terminal electrically coupled to the second component terminal.

2. The passive component module of claim 1, wherein the base includes:
a conductive metal shield having a conductive metal top that extends along the second side and a conductive metal sidewall that extends from the conductive metal top to the redistribution layer structure; and
a dielectric structure that extends between the conductive metal top and the redistribution layer structure.

3. The passive component module of claim 2, wherein:
the conductive metal trace is a first conductive metal trace;
the redistribution layer structure includes a second conductive metal trace that abuts the conductive metal sidewall; and
the redistribution layer structure includes a third terminal spaced apart from the first and second terminals and exposed along the first side, the third terminal electrically coupled to the second conductive metal trace.

4. The passive component module of claim 3, wherein:
the redistribution layer structure has a first level that includes a first trace layer, a first via layer, and the dielectric layer;
the first trace layer extends between the base and the first via layer and includes the first and second conductive metal traces;
the first via layer extends between the first trace layer and the first side and includes the first, second, and third terminals; and
the dielectric layer abuts portions of the first trace layer and the first via layer.

5. The passive component module of claim 4, wherein:
the dielectric structure of the base includes compression molded dielectric material; and
the dielectric layer of the first level includes compression molded dielectric material.

6. The passive component module of claim 3, wherein:
the dielectric layer of the first level is a first dielectric layer;
the redistribution layer structure has a second level that includes a second trace layer, a second via layer, and a second dielectric layer;
the first level extends between the base and the second level;
the second level extends between the first level and the first side;
the second trace layer extends between the first via layer and the second via layer;
the second via layer extends between the second trace layer and the first side and includes the first, second, and third terminals; and
the second dielectric layer abuts portions of the second trace layer and the second via layer.

7. The passive component module of claim 6, wherein:
the first conductive metal trace forms a first portion of the passive electronic component; and
the second trace layer includes another conductive metal trace that forms a second portion of the passive electronic component.

8. The passive component module of claim 2, wherein the redistribution layer structure includes a second passive electronic component that is electrically coupled to the passive electronic component.

9. The passive component module of claim 1, wherein the passive electronic component is a resistor.

10. The passive component module of claim 1, wherein the passive electronic component is a capacitor having a first capacitor plate and a second capacitor plate.

11. The passive component module of claim 10, wherein:
the redistribution layer structure has a first level that includes a first trace layer, a first via layer, and the dielectric layer;
the first trace layer includes the first capacitor plate;
the redistribution layer structure has a second level that includes a second trace layer, a second via layer, and a second dielectric layer;
the second trace layer includes the second capacitor plate; and
the first and second capacitor plates are separated by a portion of the dielectric layer of the first level.

12. The passive component module of claim 10, wherein:
the redistribution layer structure has a first level that includes a first trace layer, a first via layer, and the dielectric layer;
the first trace layer includes the conductive metal trace that forms the first capacitor plate;
the first trace layer includes a second conductive metal trace that forms the second capacitor plate; and
the first and second capacitor plates are separated by a portion of the dielectric layer of the first level.

13. The passive component module of claim 10, wherein the passive electronic component is a balun.

14. The passive component module of claim 10, wherein the passive electronic component is a transformer.

15. The passive component module of claim 10, wherein the passive electronic component is an inductor.

16. An electronic device, comprising:
a multilevel package substrate having a first substrate side with exposed conductive leads and an opposite second substrate side with exposed conductive pads;
a semiconductor die attached to the substrate second side and having conductive terminals electrically coupled to respective ones of the conductive pads; and
a passive component module attached to the second substrate side and including opposite first and second sides, a base extending to the second side, and a redistribution layer structure extending between the base and the first side, the redistribution layer structure including:
a passive electronic component with a first component terminal and a second component terminal;
a conductive metal trace that forms at least a portion of the passive electronic component;
a dielectric layer abutting a portion of the conductive metal trace;
a first terminal exposed along the first side and electrically coupled between the first component terminal a first one of the conductive pads of the multilevel package substrate; and
a second terminal spaced apart from the first terminal and exposed along the first side, the second terminal electrically coupled between the second component terminal and a second one of the conductive pads of the multilevel package substrate.

17. The electronic device of claim 16, wherein the base includes:
a conductive metal shield having a conductive metal top that extends along the second side and a conductive metal sidewall that extends from the conductive metal top to the redistribution layer structure; and
a dielectric structure that extends between the conductive metal top and the redistribution layer structure.

18. A method of fabricating an electronic device, the method comprising:
forming a redistribution layer structure on a base including:
forming a conductive metal trace on the base that forms at least a portion of a passive electronic component having a first component terminal and a second component terminal;
forming a dielectric layer abutting a portion of the conductive metal trace;
forming a first redistribution layer terminal exposed along a side of the redistribution layer structure and electrically coupled between two first component terminal; and
forming a second redistribution layer terminal spaced apart from the first redistribution layer terminal and exposed along the side of the redistribution layer structure, the second redistribution layer terminal electrically coupled to the second component terminal.

19. The method of claim 18, further comprising forming a conductive metal shield having a conductive metal top that extends along a side of the base and a conductive metal sidewall that extends from the conductive metal top to the redistribution layer structure.

20. The method of claim 19, wherein forming the conductive metal shield comprises:
performing a deposition process that forms the conductive metal top on a carrier; and
performing an electroplating process using a plating mask to form the conductive metal sidewall that extends from the conductive metal top.

21. The method of claim 20, further comprising:
performing a deposition process that deposits a dielectric structure over the conductive metal top and the conductive metal sidewall; and
performing a planarizing process that exposes a portion of the conductive metal sidewall through the dielectric structure along a side of the base.

22. The method of claim 21, wherein forming the conductive metal trace on the base comprises performing another electroplating process using another plating mask to form a first conductive metal trace that forms at least a portion of the passive electronic component on the dielectric structure along the side of the base, and to form a second conductive metal trace that abuts the conductive metal sidewall along the side of the base.

23. The method of claim 22, wherein:
forming the first and second redistribution layer terminals comprises performing a further electroplating process using a further plating mask to form conductive vias including the first redistribution layer terminal on a portion of the first conductive metal trace and the second redistribution layer terminal on a portion of the second conductive metal trace;
forming the dielectric layer comprises performing a compression molding process to form the dielectric layer on the first and second conductive metal traces and the conductive vias; and
the method further comprises performing another planarizing process that exposes respective portions of the first and second redistribution layer terminals through the dielectric layer along the side of the redistribution layer structure.

24. The method of claim 19, wherein:
forming the redistribution layer structure comprises forming a first redistribution level that includes the conductive metal trace, and forming a final redistribution level that includes the first and second redistribution layer terminals; and
the first redistribution level is between the base and the side of the redistribution layer structure.

25. The method of claim 24, wherein forming each individual redistribution level includes:
performing a first electroplating process using a first plating mask to form a metal trace on a side of the base or a side of a previous redistribution level;
performing a second electroplating process using a second plating mask to form a metal via on a portion of the metal trace;
performing a compression molding process to form a dielectric on the metal trace and the conductive via; and
performing a planarizing process that exposes a portion of the conductive via through the dielectric.

26. The method of claim 18, wherein:
forming the redistribution layer structure comprises forming a first redistribution level that includes the conductive metal trace, and forming a final redistribution level that includes the first and second redistribution layer terminals; and
the first redistribution level is between the base and the side of the redistribution layer structure.

27. The method of claim 26, wherein forming each individual redistribution level includes:
performing a first electroplating process using a first plating mask to form a metal trace on a side of the base or a side of a previous redistribution level;
performing a second electroplating process using a second plating mask to form a metal via on a portion of the metal trace;
performing a compression molding process to form a dielectric on the metal trace and the conductive via; and
performing a planarizing process that exposes a portion of the conductive via through the dielectric.

28. The method of claim 27, further comprising:
attaching the side of the redistribution layer structure to a lead frame or multilevel package substrate with the first and second redistribution layer terminals electrically coupled to respective conductive features of the lead frame or multilevel package substrate;
attaching a semiconductor die to the lead frame or multilevel package substrate; and
forming a package structure that encloses the semiconductor die, at least a portion of the redistribution layer structure, and at least a portion of the base.

29. The method of claim 18, further comprising:
attaching the side of the redistribution layer structure to a lead frame or multilevel package substrate with the first and second redistribution layer terminals electrically coupled to respective conductive features of the lead frame or multilevel package substrate;
attaching a semiconductor die to the lead frame or multilevel package substrate; and
forming a package structure that encloses the semiconductor die, at least a portion of the redistribution layer structure, and at least a portion of the base.
